(19) United States
(12) Patent Application Publication
(10) Pub. No.: US 2018/0308999 A1
(43) Pub. Date: Oct. 25, 2018

(54) SEMICONDUCTOR LIGHT RECEIVING DEVICE

(71) Applicant: SUMITOMO ELECTRIC INDUSTRIES, LTD., Osaka (JP)

(72) Inventors: Sundararajan Balasekaran, Osaka (JP); Hiroshi Inada, Osaka (JP)

(73) Assignee: SUMITOMO ELECTRIC INDUSTRIES, LTD., Osaka (JP)

(21) Appl. No.: 15/953,987

(22) Filed: Apr. 16, 2018

(30) Foreign Application Priority Data
Apr. 21, 2017 (JP) 2017-084735

(51) Int. Cl. H01L 31/0352; H01L 31/0304; H01L 31/109; H01L 27/144; H01L 31/18

(52) U.S. Cl. CPC H01L 31/035236; H01L 31/03046; H01L 31/109; H01L 31/022408; H01L 31/1844; H01L 27/1446; H01L 27/1443

(57) ABSTRACT

A semiconductor light receiving device includes: a substrate; and a photodiode dispose on the substrate. The photodiode has an optical absorbing layer disposed on the substrate, the optical absorbing layer having an InGaAs/GaAsSb superlattice, a first bulk semiconductor layer disposed between the substrate and the InGaAs/GaAsSb superlattice, and a second bulk semiconductor layer having a bandgap energy smaller than that of InGaAs, the second bulk semiconductor layer making contact with the first bulk semiconductor layer. The first bulk semiconductor layer includes p-type InGaAs. The second bulk semiconductor layer includes a group III antimony compound, the group III antimony compound containing gallium as group III constituent element.

### BACKGROUND OF THE INVENTION

### Field of the Invention

The present invention relates to a semiconductor light receiving device. This application claims the benefit of priority from Japanese Patent Application No. 2017-084735 filed on Apr. 21, 2017, which is herein incorporated by reference in its entirety.

### Related Background Art

B. Chen, Weiyang Jiang, Jinrong Yuan, Archie L. Holmes, Jr., and Bora. M. Onat, “SWIR/MWIR InP-Based Pin Photodiodes With InGaAs/GaAsSb Type-II Quantum Wells,” IEEE J. Quantum Electron, Vol 47, NO. 9, SEPTEMBER 2011, pp. 1244-1250 discloses a photodiode which receives light in short-wavelength and mid-wavelength infrared region.

### SUMMARY OF THE INVENTION

A semiconductor light receiving device according to one aspect of the present invention includes: a substrate; and a photodiode disposed on the substrate. The photodiode includes: an optical absorbing layer disposed on the substrate, the optical absorbing layer having an InGaAs/GaAsSb superlattice; a first bulk semiconductor layer disposed between the substrate and the InGaAs/GaAsSb superlattice; and a second bulk semiconductor layer having a bandgap energy smaller than that of InGaAs, the second bulk semiconductor layer making contact with the first bulk semiconductor layer. The first bulk semiconductor layer includes p-type InGaAs. The second bulk semiconductor layer includes a group III antimony compound, and the group III antimony compound contains gallium as group III constituent element.

### BRIEF DESCRIPTION OF THE DRAWINGS

The above-described objects and the other objects, features, and advantages of the present invention become more apparent from the following detailed description of the preferred embodiments of the present invention proceeding with reference to the attached drawings.

FIG. 1 is a schematic plan view showing a semiconductor light receiving device according to the present embodiment.

FIG. 2 is a cross sectional view taken along line II-II shown in FIG. 1.

FIG. 3 is a schematic view showing exemplary conduction and valence bands in the semiconductor light receiving device according to the embodiment.

FIG. 4A is a graph showing the optical response property of the light absorbing layer in the semiconductor light receiving device.

FIG. 4B is a graph showing the optical transmittance spectrum of the second bulk semiconductor layer in the semiconductor light receiving device.

FIG. 5A is a graph showing both the optical response property in FIG. 4A and the optical transmittance spectrum in FIG. 4B.

FIG. 5B is a graph showing a compensated optical response property obtained by combining the light absorbing layer with the second bulk semiconductor layer.

FIG. 6 is a graph illustrating the optical response characteristics of the semiconductor light receiving device in the example.

FIG. 7A is a schematic view showing a major step in a method of fabricating a semiconductor light receiving device according to the embodiment, specifically a process for forming an epitaxial substrate.

FIG. 7B is a schematic view showing a major step in the method according to the embodiment specifically a process for forming a mask on the epitaxial substrate.

FIG. 8A is a schematic view showing a major step in the method according to the embodiment, specifically a process for producing a mesa from the epitaxial substrate with the mask by etching.

FIG. 8B is a schematic view showing a major step in the method according to the embodiment, specifically a process for forming a passivation film and electrodes.

### DESCRIPTION OF THE EMBODIMENTS

A semiconductor light receiving device that receives light in a certain wavelength band can provide a one-dimensional or two-dimensional image, which has the distribution of wavelengths of light from an object. Inventors' findings reveal that, for example, an InGaAs/GaAsSb superlattice has a photo response property with good flatness in the wavelength region of 1.7 micrometers or more and heavy dependence on optical wavelengths in the short wavelength region of less than 1.7 micrometers and that the semiconductor light receiving device that has the InGaAs/GaAsSb superlattice has an intrinsic difference in photo response between the above wavelength regions. This difference in photo response deforms the spectrum of an optical signal indicating the property of an article to be measured.

It is an object of one aspect of the present invention is to provide a semiconductor light receiving device, which includes an InGaAs/GaAsSb superlattice, having the photo response with a desired flatness.

Specific embodiments will be described below.

A semiconductor light receiving device according to an embodiment includes: (a) a substrate; and (b) a photodiode disposed on the substrate. The photodiode includes: an optical absorbing layer disposed on the substrate, the optical absorbing layer having an InGaAs/GaAsSb superlattice; a first bulk semiconductor layer disposed between the substrate and the InGaAs/GaAsSb superlattice; and a second bulk semiconductor layer having a bandgap energy smaller than that of InGaAs, the second bulk semiconductor layer making contact with the first bulk semiconductor layer. The first bulk semiconductor layer includes p-type InGaAs. The second bulk semiconductor layer includes a group III antimony compound, and the group III antimony compound contains gallium as group III constituent element.

The semiconductor light receiving device includes the photodiode which receives light through the substrate. The light is incident on the substrate and passes through the second bulk semiconductor layer of the p-type group-III antimony compound to enter the InGaAs/GaAsSb superlattice. The InGaAs/GaAsSb superlattice of the light absorbing layer has optical response characteristics monotonically increasing in a short wavelength region of 1.7 micrometers or less. The second bulk semiconductor layer absorbs light in the short wavelength region of less than 1.7 micrometers, and exhibits a high optical transmittance in a long wave light region of 1.7 micrometers or more. Combining the InGaAs/GaAsSb superlattice with the second bulk semiconductor layer can provide the semiconductor light receiving device with flat response characteristics in the wavelength region of 1.7 to 2.3 micrometers. The second bulk semiconductor layer does not hinder the flow of holes from the InGaAs/GaAsSb superlattice. The second bulk semiconductor layer has a bandgap smaller than that of InGaAs, and the p-type conductivity of the second bulk semiconductor layer adjoining the first bulk semiconductor layer allows the valence band of the second bulk semiconductor layer to be close to that of the first bulk semiconductor layer. The second bulk semiconductor layer has a conduction band lower than that of the first bulk semiconductor, and the arrangement of the first and second bulk semiconductor layers can provide a band offset in the conduction band to form a well, and the well hinders electron from flowing to contribute to reduction in dark current.

The semiconductor light receiving device according to an embodiment, the second bulk semiconductor layer includes p-type GaSb.

In the semiconductor light receiving device, the second bulk semiconductor layer of binary compound has a window in the wavelength band in which the InGaAs/GaAsSb superlattice exhibits a flat optical absorption characteristic.

The semiconductor light receiving device according to an embodiment further includes a p-type InGaAs semiconductor layer disposed between the substrate and the second bulk semiconductor layer. The second bulk semiconductor layer is in contact with the p-type InGaAs semiconductor layer, and the first bulk semiconductor layer has a thickness larger than that of the p-type InGaAs semiconductor layer.

The semiconductor light receiving device may dispose the second bulk semiconductor layer between the two p-type InGaAs semiconductors in direct contact with these p-type InGaAs semiconductors.

The semiconductor light receiving device according to an embodiment, the substrate includes p-type InP.

In the semiconductor light receiving device, the substrate of p-type InP is transparent to light of wavelengths in which the optical characteristics has a flatness provided by the combination of the InGaAs/GaAsSb superlattice with the second bulk semiconductor layer.

Teachings of the present invention can be readily understood by considering the following detailed description with reference to the accompanying drawings shown as examples. Referring to the accompanying drawings, embodiments of a semiconductor light receiving device, and a method for fabricating a semiconductor light receiving device according to the present invention will be described below. To facilitate understanding, identical reference numerals are used, where possible, to designate identical elements that are common to the figures.

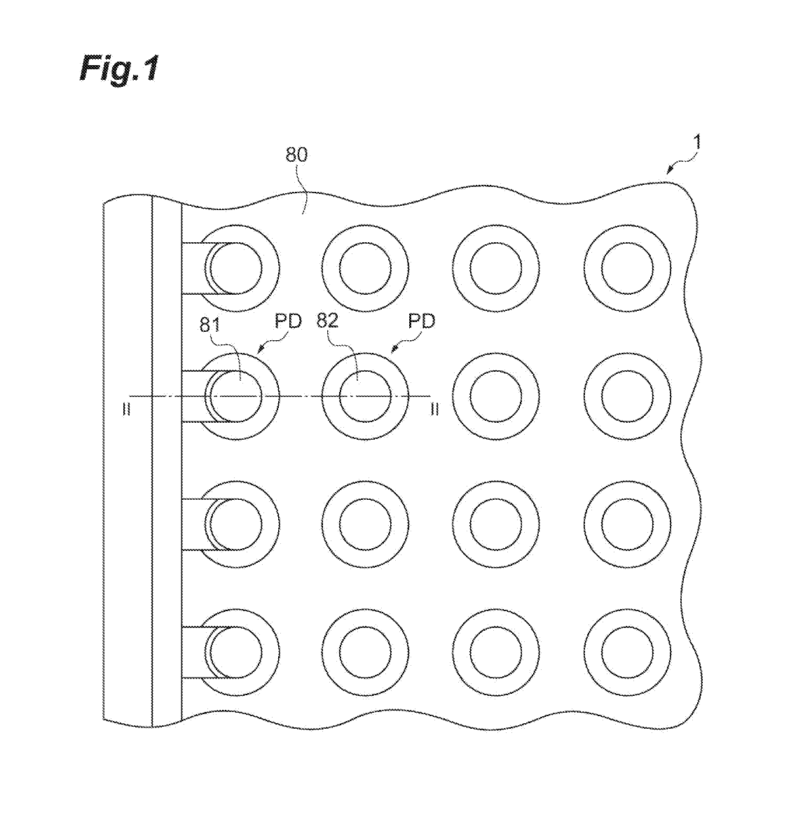

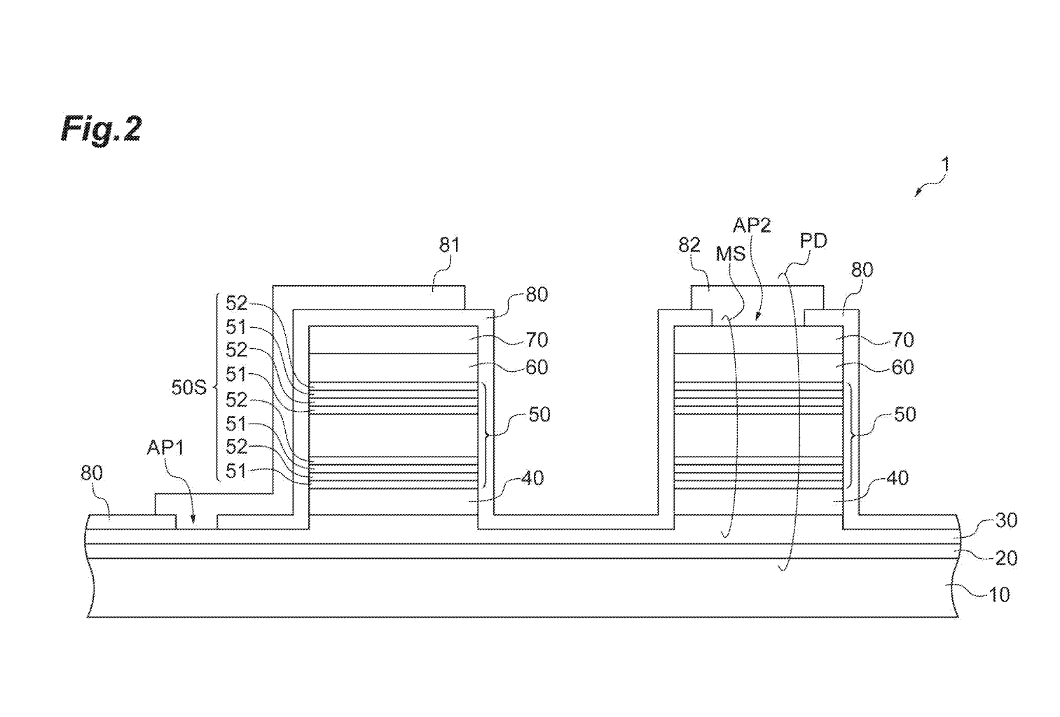

FIG. 1 is a schematic plan view showing a semiconductor light receiving device according to the present embodiment, and FIG. 2 is a cross sectional view taken along line II-II shown in FIG. 1. As shown in FIGS. 1 and 2, the semiconductor light receiving device 1 includes a substrate 10 and one or more photodiodes PD, which are disposed on the substrate 10. In the semiconductor light receiving device 1, the photodiodes PD can be arranged to form one-dimensionally or two-dimensional array.

In the following description, a single photodiode PD in the array will be described with reference to FIG. 2. The photodiode PD of the semiconductor light receiving device 1 includes a light absorbing layer 50, a first bulk semiconductor layer 40, and a second bulk semiconductor layer 30. The light absorbing layer 50 is disposed on the substrate 10. The first bulk semiconductor layer 40 is disposed between the light absorbing layer 50 and the substrate 10, and includes p-type InGaAs. The second bulk semiconductor layer 30 is disposed between the first bulk semiconductor layer 40 and the substrate 10. The second bulk semiconductor layer 30 has a bandgap smaller than that of InGaAs, and includes a group-III antimony compound of p-type conductivity. The p-type group-III antimony compound may contain antimony as group V constituent element and gallium as a group III constituent element, and can be, for example, GaSb. The first bulk semiconductor layer 40 is disposed between the second bulk semiconductor layer 30 and the light absorbing layer 50, and is in contact with the second bulk semiconductor layer 30. The light absorbing layer 50 includes InGaAs layers 51 and GaAsSb layers 52, which are alternately arranged to form an InGaAs/GaAsSb superlattice 50S. The superlattice 50S receives light, which passes through the substrate 10, from the external of the semiconductor light receiving device 1, and this light further passes through the p-type group III antimony compound of the second bulk semiconductor layer 30 to the light absorbing layer 50. The p-type InGaAs of the first bulk semiconductor layer 40 is disposed between the second bulk semiconductor layer 30 and the light absorbing layer 50, so that the first bulk semiconductor layer 40 forms a barrier to minority carriers and hinders the minority carriers in the second bulk semiconductor layer 30 from diffusing to flow into the light absorbing layer 50. A bulk semiconductor layer has such a thickness that the interface between the bulk semiconductor layer and the semiconductor layer making contact with the bulk semiconductor layer does not exert specific effects from the interface on the whole of the bulk semiconductor layer.

The semiconductor light receiving device 1 allows the photodiode PD to receive light through the substrate 10. The light thus received passes through the second bulk semiconductor layer 30 of the p-type group III antimony compound to enter the InGaAs/GaAsSb superlattice 50S. The InGaAs/GaAsSb superlattice 50S of the light absorbing layer 50 has an optical response property which monotonically increases in a short wavelength region of 1.7 micrometers or less. The second bulk semiconductor layer 30 absorbs light in the short wavelength region of less than 1.7 micrometers, and exhibits high optical transmittance in a long wave light region of 1.7 micrometers or more. The combination of the InGaAs/GaAsSb superlattice 50S with the second bulk semiconductor layer 30 can provide the semiconductor light receiving device 1 with the optical response property of good flatness in the wavelength region of 1.7 to 2.3 micrometers. The second bulk semiconductor layer 30 does not interfere with the flow of holes from the InGaAs/GaAsSb superlattice 50S. The second bulk semiconductor layer 30 has a bandgap smaller than that of InGaAs, and the p-type conductivity of the second bulk semiconductor layer 30 adjoining to the first bulk semiconductor layer 40 makes the valence band Ev30 of the second bulk semiconductor layer 30 close to the valence band Ev40 of the bulk semiconductor layer 40. The second bulk semiconductor layer 30 has a conduction band Ec30 lower than the conduction band Ec40 of the first bulk semiconductor layer 40. In the conduction band Ec, the second bulk semiconductor layer 30 provides a band offset, which is effective in forming a well QW, with respect to the first bulk semiconductor layer 40, and this well QW hinders electrons from flowing therethrough to reduce dark current.

The photodiode PD may further include a p-type InGaAs semiconductor layer 20. The p-type InGaAs semiconductor layer 20, the second bulk semiconductor layer 30, and the first bulk semiconductor layer 40 are arranged such that the second bulk semiconductor layer 30 is disposed between the p-type InGaAs semiconductor layer 20 and the first bulk semiconductor layer 40. In the embodiment, the p-type InGaAs semiconductor layer 20 is in direct contact with the second bulk semiconductor layer 30. The p-type InGaAs semiconductor layer 20, which can be referred to as a buffer layer, can make contact with the second bulk semiconductor layer 30 to form an interface smoother than the surface of the substrate 10. The p-type InGaAs semiconductor layer 20 has a thickness smaller than that of the first bulk semiconductor layer 40, and this small thickness allows holes to tunnel the p-type InGaAs semiconductor layer 20, so that the p-type InGaAs semiconductor layer 20 does not interfere with the flow of holes from the InGaAs/GaAsSb lattice 50S. The p-type InGaAs semiconductor layer 20 is disposed between the substrate 10 and the second bulk semiconductor layer 30.

The photodiode PD further includes an InGaAs semiconductor layer 60 and an n-type contact layer 70, and the InGaAs semiconductor layer 60 and the n-type contact layer 70 are disposed on the light absorbing layer 50.

An exemplary semiconductor light receiving device 1.

Substrate 10: InP semiconductor wafer having a thickness of 0.5 to 15 micrometers, Fe concentration of 1×10¹⁸ cm⁻³ and a plane orientation of (100) plane; and made of Fe-doped InP semiconductor.

P-type InGaAs semiconductor layer 20: p-type InGaAs of a thickness of 10 to 100 nm and a p-type dopant concentration of 1×10¹⁶ to 5×10¹⁶ cm⁻³.

Second bulk semiconductor layer 30: p-type GaSb having a thickness of 300 to 500 nm, and a p-type dopant concentration of a 1×10¹⁶ to 5×10¹⁶ cm⁻³.

First bulk semiconductor layer 40: p-type InGaAs having a thickness of 300 to 500 nm, and a p-type dopant concentration of 1×10¹⁶ to 1×10¹⁷ cm⁻³, and a p-type dopant of beryllium.

InGaAs/GaAsSb superlattice: InGaAs having a thickness of 2 to 7 nm and a dopant concentration of 1×10¹⁴ to 1×10¹⁵ cm⁻³ (background doping level); and GaAsSb having a thickness of 2 to 7 nm and a dopant concentration of 1×10¹⁴ to 1×10¹⁵ cm⁻³ (background doping level); and the light absorbing layer having a thickness of 1000 nm and having the stacking number of layers, 200.

Undoped InGaAs semiconductor layer 60: InGaAs having a thickness of 300 to 1000 nm.

N-type contact layer 70: Si-doped InP having a thickness of 300 to 500 nm, and an Si concentration of 1×10¹⁸ to 5×10¹⁸ cm⁻³.

In the present embodiment, the p-type GaSb of the second bulk semiconductor layer 30 is disposed between the p-type InGaAs of the first bulk semiconductor layer 40 and the p-type InGaAs semiconductor layer 20, and is in direct contact with the p-type InGaAs and the p-type InGaAs semiconductor layer 20. The arrangement of the p-type InGaAs, p-type GaSb and p-type InGaAs allows the p-type GaSb to absorb light of short wavelengths in a range of 1.7 micrometers or less, so that the photodiode has a flat dependence of an optical response on wavelength, and the two p-type InGaAs layers blocks minority carriers, which the p-type GaSb located between the two p-type InGaAs layers generates, to reduce dark current in a range of room temperature or lower.

The photodiode PD has a semiconductor mesa MS, which includes an upper portion of the second bulk semiconductor layer 30, the first bulk semiconductor layer 40, the light absorbing layer 50, the InGaAs semiconductor layer 60, and the n-type contact layer 70. In the photodiode PD, the p-type InGaAs semiconductor layer 20, the second bulk semiconductor layer 30, the first bulk semiconductor layer 40, the light absorbing layer 50, the InGaAs semiconductor layer 60, and the n-type contact layer 70 are arranged in order on the substrate 10. In the semiconductor mesa MS, the second bulk semiconductor layer 30 is located between the first bulk semiconductor layer 40 and the p-type InGaAs semiconductor layer 20, and is in contact with the first bulk semiconductor layer 40 and the p-type InGaAs semiconductor layer 20. The first bulk semiconductor layer 40 may have a thickness greater than that of the p-type InGaAs semiconductor layer 20. The light absorbing layer 50 in the semiconductor mesa MS receives light through the substrate 10. This light passes through the second bulk semiconductor layer 30 of p-type group III antimony compound, and then enters the light absorbing layer 50 (InGaAs/GaAsSb superlattice 50S). The photodiode PD exhibits an optical response property that the light transmitting property (or the light absorbing property) of the second bulk semiconductor layer 30 made of p-type group III antimony compound compensates for, instead of the inherent optical response property of the InGaAs/GaAsSb superlattice structure in the light absorbing layer 50.

Referring to FIGS. 1 and 2, the semiconductor light receiving device 1 includes a first electrode 81 and a second electrode 82. The first electrode 81 is disposed on the top face of the semiconductor mesa MS, and may be one of a cathode electrode and an anode electrode, and in the embodiment, the first electrode 81 is connected to the n-type contact layer 70 to work as a cathode. The second electrode 82 is disposed on the substrate 10, and may be the other of the cathode electrode and the anode electrode, and in the embodiment, the second electrode 82 is connected to a p-type semiconductor, such as the second bulk semiconductor layer 30, to work as an anode. The first and second electrodes 81 and 82 are in contact with the semiconductor region via the first and second openings AP1 and AP 2 of the passivation film 80, respectively. The first and second electrodes 81 and 82 may include, for example, AuTi/AuZnAu (for p-side electrode) and Au—Ge—Ni (for n-side electrode), respectively. The passivation film 80 may include, for example, SiN or SiON.

### EXAMPLE

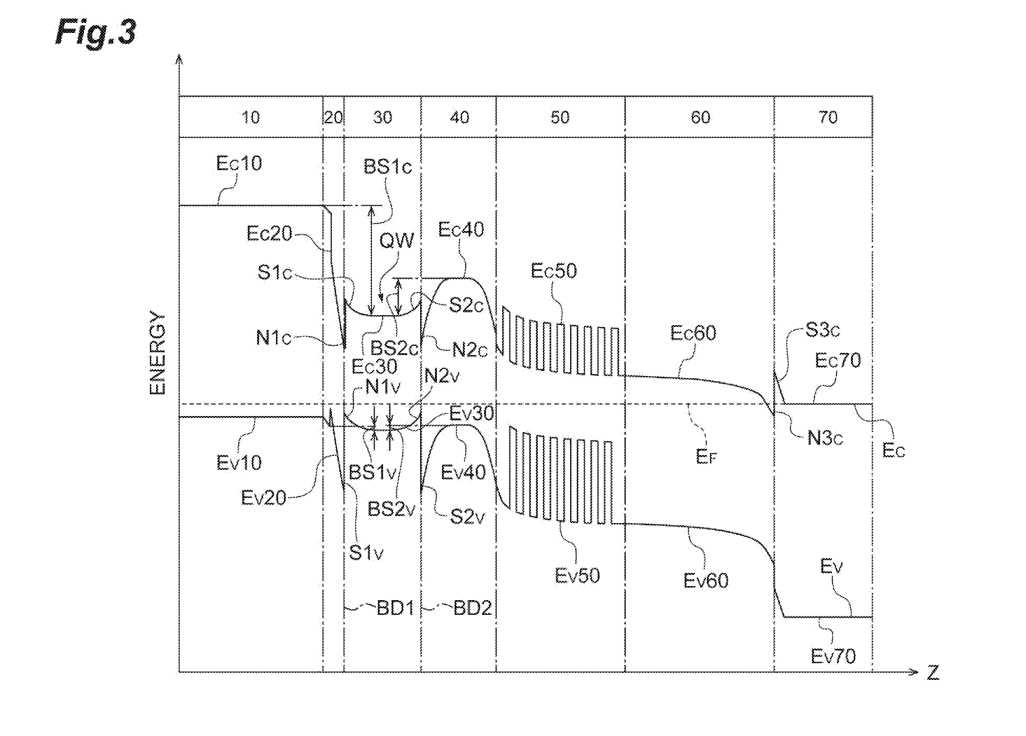

FIG. 3 is a diagram showing the conduction and valence bands in the semiconductor light receiving device in the example.

The second bulk semiconductor layer 30 has a bandgap smaller than that of InGaAs, and includes, for example, a p-type GaSb bulk. In the valence band Ev of the photodiode PD according to the embodiment, the valence band Ev30 of the second bulk semiconductor layer 30 has a level close to that of the valence band Ev40 of the first bulk semiconductor layer 40. The valence band has a first offset BS1v, which has a small value, defined as a level difference between the valence band Ev30 of the second bulk semiconductor layer 30 and the valence band Ev20 of the p-type InGaAs semiconductor of the p-type InGaAs semiconductor layer 20 which are apart from their interface including a notch and a spike. The valence band also has a second band offset BS2v, which has a small value, defined as a level difference between the valence band Ev30 of the second bulk semiconductor layer 30 and the level of the valence band Ev40 of the p-type InGaAs of the first bulk semiconductor layer 40, which are away from their interface including a notch and a spike.

Exemplary first and second valence band offsets BS1v and BS2v.

First valence band offset BS1v: 80 to 100 meV.

Second valence band offset BS2v: 60 to 80 meV.

These values for the band offsets indicate that no substantial well is formed in the valence band Ev30 of the second bulk semiconductor layer 30, and the second bulk semiconductor layer 30 does not prevent holes from the InGaAs/GaAsSb superlattice 50S from flowing therethrough.

In the valence band Ev, specifically, the valence band Ev30 of the second bulk semiconductor layer 30 has a notch N1v at the boundary BD1 between the second bulk semiconductor layer 30 and the p-type InGaAs semiconductor layer 20, and another notch N2v at the boundary BD2 between the bulk semiconductor layer 30 and the first bulk semiconductor layer 40. The valence band Ev20 of the p-type InGaAs semiconductor layer 20 has a spike S1v at the boundary BD1 between the p-type InGaAs semiconductor layer 20 and the second bulk semiconductor layer 30, and the valence band Ev40 of the first bulk semiconductor layer 40 has a spike S2v at the boundary BD2 between the first bulk semiconductor layer 40 and the second bulk semiconductor layer 30. The notch N1v has an amplitude smaller than that of the spike S1v, and the notch N2v has an amplitude smaller than that of the spike S2v. Holes from the light absorbing layer 50 can pass through the spikes S1v and S2v by tunnel, and the second bulk semiconductor layer 30 does not prevent holes from the InGaAs/GaAsSb superlattice from flowing therethrough.

As described above, the second bulk semiconductor layer 30 according to the embodiment includes a p-type GaSb bulk layer, which has a bandgap smaller than that of, for example, an InGaAs bulk layer, and in view of the band alignment in the valence band Ev in photodiode PD, the p-type InGaAs and p-type GaSb bulk layers make the level of the valence band Ev30 of the second bulk semiconductor layer 30 close to that of the valence band Ev40 of the first bulk semiconductor layer 40.

The above band alignment of the valence band Ev enables the following band alignment with the conduction band Ec. In the conduction band Ec, the second bulk semiconductor layer 30 has a conduction band Ec30 lower than that of the substrate 10, the conduction band Ec20 of the p-type InGaAs semiconductor layer 20 and the conduction band Ec40 of the first bulk semiconductor layer 40, and the conduction band has first and second offsets BS1c and BS2c.

Exemplary first and second conduction band offsets BS1c and BS2c.

First conduction band offset BS1c: 600 to 675 meV.

Second conduction band offset BS2c: 200 to 250 meV.

The conduction band Ec30 of the second bulk semiconductor layer 30 forms a well QW with respect to the conduction band Ec20 of the p-type InGaAs semiconductor layer 20 and the conduction band Ec40 of the first bulk semiconductor layer 40. The well QW captures electrons to hinder electrons from flow therethrough, and can contribute to reduction in dark current.

The band offsets in the conduction band Ec are greater than those in the valence band, and these band offsets can makes the well in the conduction band Ec larger than that in the valence band. The arrangement of the p-type InGaAs semiconductor layer 20, the p-type bulk GaSb of the second bulk semiconductor layer 30, and the p-type InGaAs bulk of the first bulk semiconductor layer 40 can make an energy level of the valence band substantially flat, and can provide the conduction band with the well effective in capturing carriers. The p-type GaSb bulk layer of the second bulk semiconductor layer 30 can provide the photodiode PD with an adjusted photo response property.

In the conduction band Ec, specifically, the conduction band Ec30 of the second bulk semiconductor layer 30 has a spike S1c at the boundary BD1 between the second bulk semiconductor layer 30 and the p-type InGaAs semiconductor layer 20, and a spike S2c at the boundary BD2 between the layer 30 and the first bulk semiconductor layer 40. The conduction band Ec20 of the p-type InGaAs semiconductor layer 20 has a notch N1c at the boundary BD1 between the p-type InGaAs semiconductor layer 20 and the second bulk semiconductor layer 30, and the conduction band Ec 40 of the first bulk semiconductor layer 40 has a notch N2c at the boundary BD2 between the bulk semiconductor layer 40 and the second bulk semiconductor layer 30.

Comparison the spikes S1c and S2c of the conduction band Ec with the spikes S1v and S2v of the valence band Ev reveals that the spikes S1v S2v of the valence band Ev are larger than the spikes S1c and S2c of the conduction band Ec. Comparison of the notches N1c and N2c of the conduction band Ec with the notches N1v and N2v of the valence band Ev reveals that the notches N1c and N2c of the conduction band Ec are larger than the notches N1v and N2v of the valence band Ev.

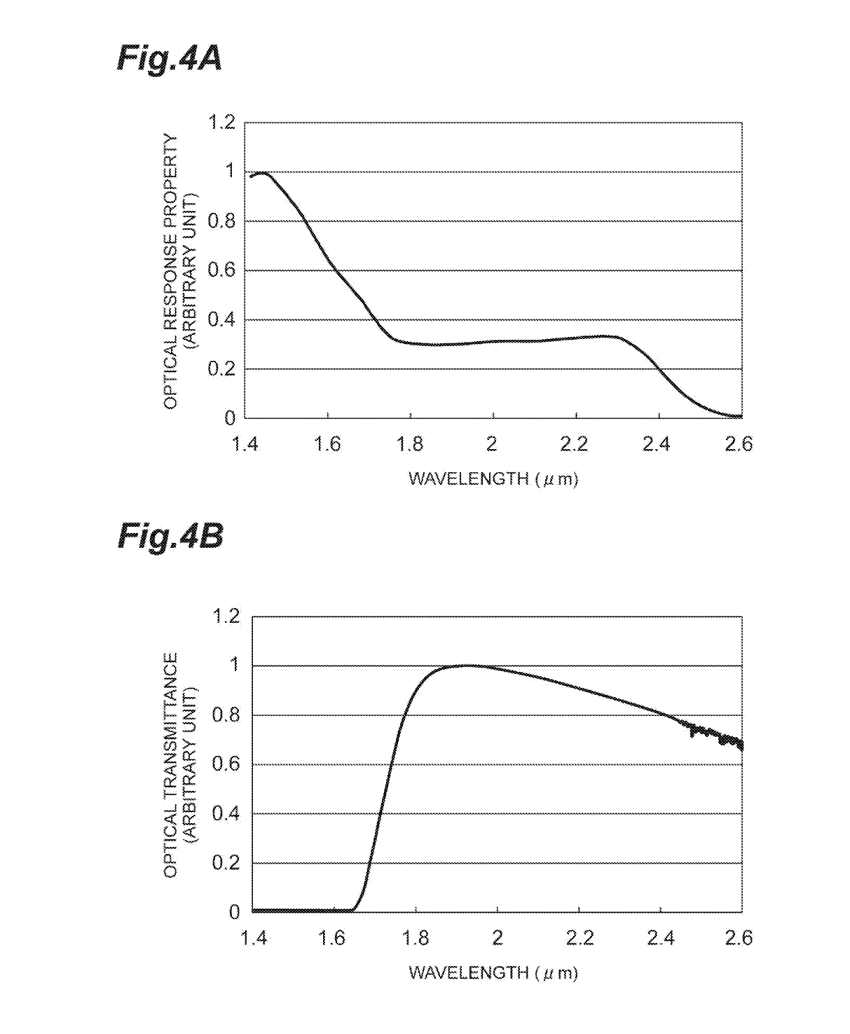

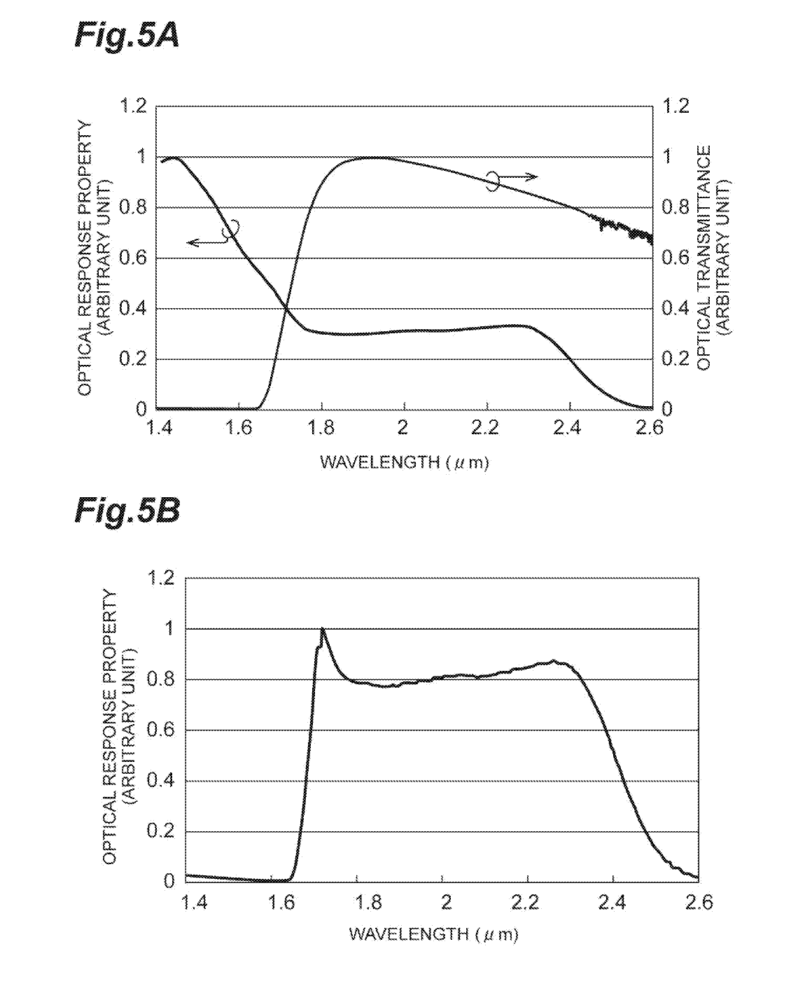

FIGS. 4A and 4B are graphs showing the optical response property of the light absorbing layer of the semiconductor light receiving device according to the example, and the optical transmittance spectrum of the second bulk semiconductor layer of the semiconductor light receiving device, respectively. Measurements are carried out at an absolute temperature of 213 degrees to obtain the photo response property in FIG. 4A and the optical transmittance spectrum in FIG. 4B, which are normalized by respective maxima. FIG. 5A is a graph showing the superposition of the light response spectrum of the InGaAs/GaAsSb superlattice shown in FIG. 4A on the optical transmittance spectrum of the p-type GaSb bulk layer shown in FIG. 4B, and FIG. 5B is a graph showing a photo response property provided by the superposition of the optical transmittance spectrum of the p-type GaSb bulk layer shown in FIG. 4B on the optical response property of the InGaAs/GaAsSb superlattice that compensates for the optical response property of the InGaAs/GaAsSb superlattice.

Measurements are carried out at an absolute temperature of 213 degrees to obtain the photo response property in FIG. 5A and the optical transmittance spectrum in FIG. 5B, which are normalized by their maxima.

Referring to FIG. 4A, the photo response property of the InGaAs/GaAsSb superlattice of the light absorbing layer monotonically increases in the short wavelength region of 1.7 micrometers or less. Referring to FIG. 4B, the p-type bulk GaSb of the second bulk semiconductor layer exhibits a low optical transmittance in the short wavelength region of less than 1.7 micrometers, and a high optical transmittance in the long wavelength region of 1.7 micrometers or more. Inventors' studies shows that, the p-type bulk GaSb (the second bulk semiconductor layer) compensates the optical response property of the InGaAs/GaAsSb superlattice (the light absorbing layer) for its non-flatness to provide the photodiode with an optical response property having satisfactory flatness in the wavelength range of 1.7 micrometers or more and 2.3 micrometers or less. The second bulk semiconductor layer composed of the binary compound, e.g., p-type bulk GaSb, has an optical transmissive range with less dependence on wavelength (transmission window) in a flat part of the light absorption property of the InGaAs/GaAsSb superlattice, specifically, a wavelength range of 1.8 (inclusive) to 2.3 micrometers (inclusive), and has a monotonically changing transmittance (absorption range) in the wavelength band in a varying part of the light absorption property of the InGaAs/GaAsSb superlattice, specifically, a wavelength range of 1.8 (inclusive) to 2.3 micrometers (inclusive). The semiconductor light receiving device is provided with a compensated optical response property provided by the light absorbing layer (the InGaAs/GaAsSb superlattice) and the second bulk semiconductor layer.

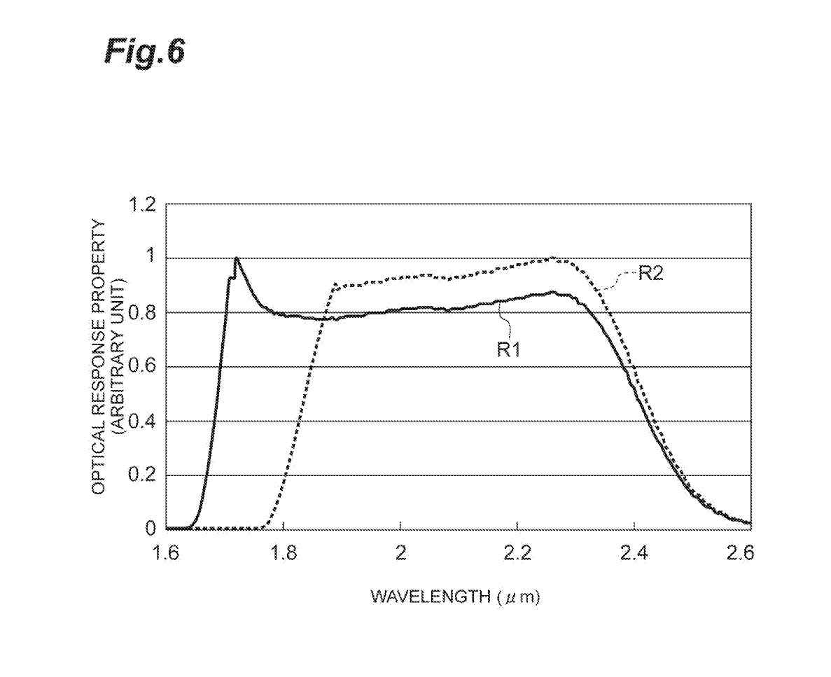

FIG. 6 is a graph showing normalized photo response properties of an InGaAs/GaAsSb superlattice at absolute temperatures of 213 and 300 degrees. Referring to FIG. 6, the optical response curve (R1) at the absolute temperature of 213 degrees and the optical response property (R2) at the absolute temperature of 300 degrees.

These optical response characteristics (R1 and R2) have good flatness in the wavelength range of 1.9 to 2.3 micrometers. Specifically, the optical response property (R1) at an absolute temperature of 213 degrees has good flatness in a wavelength range of 1.7 micrometers or more and 2.3 micrometers or less.

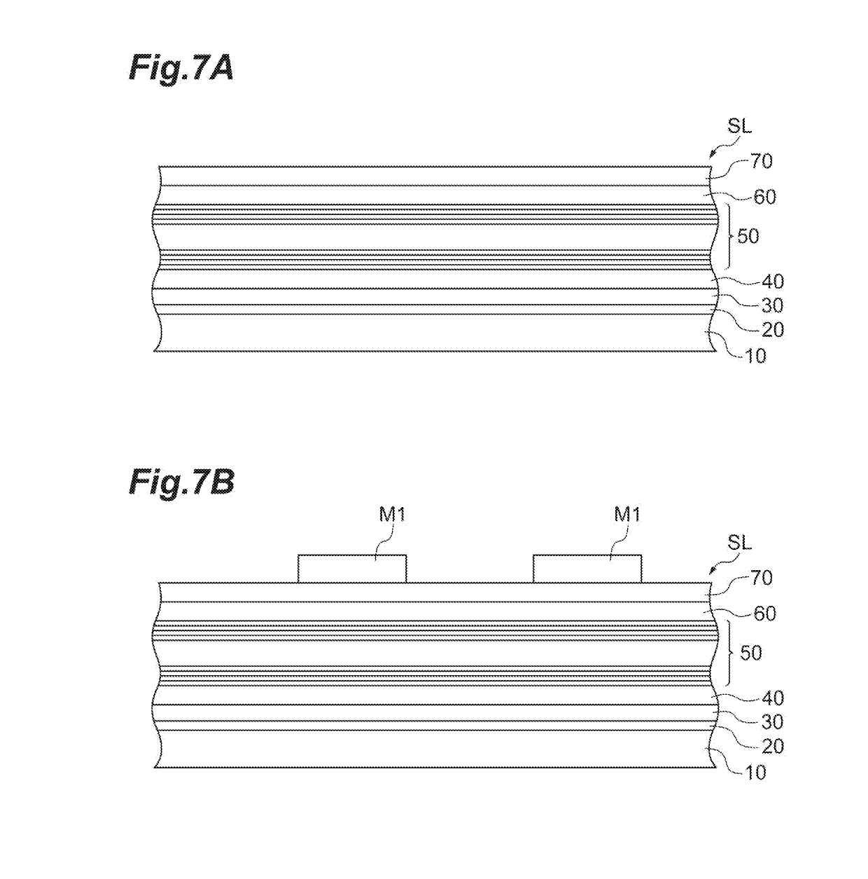

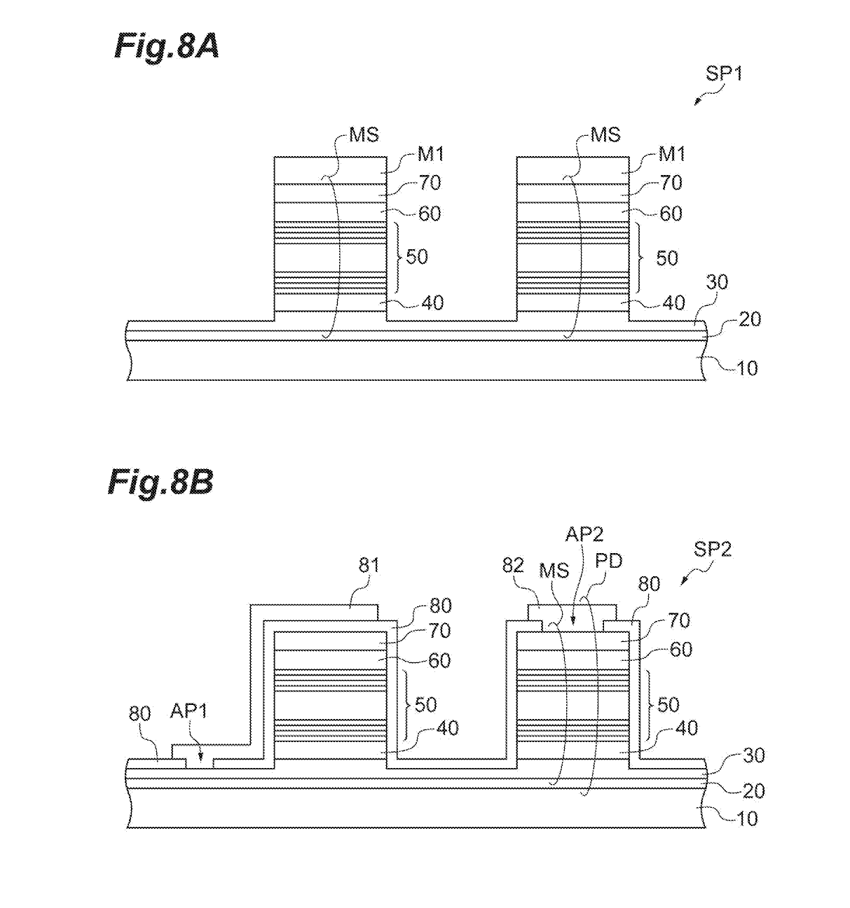

With reference to FIGS. 7A, 7B, 8A, and 8B, a method for fabricating a semiconductor light receiving device will be described below. To facilitate understanding, reference numerals used in FIGS. 1 and 2 are used below where possible.

In fabrication of a semiconductor light receiving device, a substrate 10, such as an InP wafer, is prepared for crystal growth. As shown in FIG. 7A, the p-type InGaAs semiconductor layer 20, the second bulk semiconductor layer 30, the first bulk semiconductor layer 40, the light absorbing layer 50, the InGaAs semiconductor layer 60, and the n-type contact layer 70 are grown on the substrate 10 to form a semiconductor laminate SL. The growth of semiconductor layers is carried out, for example, by molecular beam epitaxy, referred to as “MBE”.

As shown in FIG. 7B, a first mask M1 defining the shape of the semiconductor mesa MS is formed on the principal surface of the semiconductor laminate SL. The first mask M1 includes, for example, SiN or SiO₂.

As shown in FIG. 8A, the semiconductor laminate SL is etched with the first mask M1 to form a semiconductor mesa MS. This etching is stopped in the second bulk semiconductor layer 30, and can be a dry etching which uses hydrogen iodide or silicon chloride gas as an etchant. After the semiconductor mesa MS is formed, the first mask M1 is removed to obtain the substrate product SP1.

As shown in FIG. 8B, after the removal of the first mask Ml, the first and second electrodes 81 and 82 are formed to obtain the semiconductor light receiving device 1. Specifically, after the removal of the first mask M1, a passivation film 80 is grown to cover the semiconductor mesa MS and the etched second bulk semiconductor layer 30. The passivation film 80 is grown by a film formation method, such as plasma CVD. A second mask M2 is formed on the passivation film 80 and has an opening for electrical connection to the first and second electrodes 81 and 82. The second mask M2 includes, for example, resist. The passivation film 80 is etched with the second mask M2 to form the first and second openings AP1 and AP2 in the passivation film 80. After this etching, the second mask M2 is removed, and a lift-off mask is formed to pattern the first and second electrodes 81 and 82. The lift-off mask has an opening defining the shape of the first electrode 81, which allows it to be in contact with the top surface of the semiconductor mesa MS, and an opening defining the shape of the second electrode 82, which allows it to be in contact with the n-type contact layer 70. A metal film is deposited on the lift-off mask by vapor deposition. The lift-off mask is removed by liftoff to leave the first and second electrodes 81 and 82 on the substrate product SP1, thereby obtaining a substrate product SP2. The substrate product SP2 is broken by cleavage to form the semiconductor light receiving device 1. If necessary, the backside of the substrate 10 of the substrate product SP2 can be polished prior to the cleavage.

As described above, the present embodiment allows the semiconductor light receiving device including an InGaAs/GaAsSb superlattice to exhibit a desired flatness in the photo response property.

Having described and illustrated the principle of the invention in a preferred embodiment thereof, it is appreciated by those having skill in the art that the invention can be modified in arrangement and detail without departing from such principles. We therefore claim all modifications and variations coining within the spirit and scope of the following claims.

What is claimed is:

1. A semiconductor light receiving device comprising:
a substrate; and
a photodiode disposed on the substrate,
the photodiode including:
an optical absorbing layer disposed on the substrate, the optical absorbing layer having an InGaAs/GaAsSb superlattice,
a first bulk semiconductor layer disposed between the substrate and the InGaAs/GaAsSb superlattice, and
a second bulk semiconductor layer having a bandgap energy smaller than that of InGaAs, the second bulk semiconductor layer being in contact with the first bulk semiconductor layer,
the first bulk semiconductor layer including p-type InGaAs,
the second bulk semiconductor layer including a group III antimony compound, the group III antimony compound containing gallium as group III constituent element.

2. The semiconductor light receiving device according to claim 1, wherein the second bulk semiconductor layer includes p-type GaSb.

3. The semiconductor light receiving device according to claim 1, further comprising a p-type InGaAs semiconductor layer disposed between the substrate and the second bulk semiconductor layer,
wherein the second bulk semiconductor layer is in contact with the p-type InGaAs semiconductor layer, and the first bulk semiconductor layer has a thickness larger than that of the p-type InGaAs semiconductor layer.

4. The semiconductor light receiving device according to claim 1, wherein the substrate includes p-type InP.
